(19) United States
(12) Patent Application Publication
(10) Pub. No.: US 2011/0029271 A1
(43) Pub. Date: Feb. 3, 2011

(54) METHOD OF INSPECTING MOTOR CONDITION AND DEVICE FOR INSPECTING MOTOR CHARACTERISTICS

(75) Inventor: Akihiko Takahashi, Nagano (JP)

Correspondence Address: RANKIN, HILL & CLARK LLP, 38210 GLENN AVENUE, WILLOUGHBY, OH, 44094-7808, US

(73) Assignee: SANYO DENKI CO., LTD., Tokyo (JP)

(21) Appl. No.: 12/845,259

(22) Filed: Jul. 28, 2010

(30) Foreign Application Priority Data
Jul. 29, 2009 (JP) 2009-177091

(51) Int. Cl. G01R 31/34

(52) U.S. Cl. 702/115

(57) ABSTRACT

A method of inspecting motor condition, which allows inspection of a condition of a motor installed in an apparatus without removing the motor from the apparatus, is provided. A device for inspecting motor characteristics includes: a measuring section for measuring a frequency value and an amplitude value of a waveform of a counter electromotive force generated when a mover of the motor is moved by an external force; and a computing section for computing a counter electromotive force constant on the basis of the frequency value and the amplitude value. An armature winding of the motor and the inspecting device are electrically connected with a power supply line disconnected from the motor. An external force is applied to the mover of the motor. A condition of the motor is determined on the basis of the computed result.

### TECHNICAL FIELD

The present invention relates to a method of inspecting a condition of a motor that generates a counter electromotive force or counter electromotive voltage when a mover of the motor is moved by an external force, and to a device for inspecting motor characteristics.

### BACKGROUND ART

Japanese Patent Application Publication No. 2002-131153 (JP 2002-131153 A) discloses a torque measuring device for measuring a torque without using a torque meter. Japanese Patent Application Publication No. 61-124256 (JP 60-124256 A) discloses a method of measuring a thrust generated by a voice-coil linear motor by applying an external force for reciprocating a coil of the linear motor to calculate a thrust constant.

In existing motor condition inspection methods and motor characteristic inspecting devices, power is supplied to a motor to drive the motor at a constant rotational speed, and an output of the motor is measured to inspect characteristics of the motor such as a torque. Therefore, it is necessary to use, for example, a voltmeter, a tachometer, or a speed sensor for inspection to perform necessary measurement. Thus, in the related art, a motor installed in an apparatus is not directly inspected, and it is necessary to remove the motor from the apparatus and mount the motor on a dedicated inspecting device in order to inspect characteristics of the motor. Therefore, it is necessary to remove the motor from the apparatus for each regular checking or inspection, which consumes substantial labor and time required for the inspection. The installation condition of the motor cannot be inspected if the motor is removed from the apparatus.

For a linear motor, in particular, the installation condition of a mover and a stator (whether or not a so-called air gap is proper) affects an output of the motor. In the related art, a gap gauge is inserted into a gap formed between the mover and the stator to measure mechanical dimensions in order to inspect the installation condition. In this case, however, inspection is performed with the motor removed from the apparatus, and thus a mechanical error may likely occur when the motor is reinstalled in the apparatus after the inspection. Also, it is difficult to inspect whether or not the gap formed between the mover and the stator is totally uniform.

### SUMMARY OF INVENTION

An object of the present invention is to provide a method of inspecting motor conditions and a device for inspecting motor characteristics allowing inspection of a motor installed in an apparatus without removing the motor from the apparatus.

Another object of the present invention is to provide a method of inspecting motor conditions and a device for inspecting motor characteristics allowing inspection as to whether or not a motor is properly installed in a convenient way.

The present invention is directed to a method of inspecting motor conditions and a device for inspecting motor characteristics allowing inspection of a condition of a motor installed in an apparatus without removing the motor from the apparatus.

In the method according to the present invention, a device for inspecting motor characteristics is prepared. The device for inspecting motor characteristics includes: a measuring section for measuring a frequency value and an amplitude value of a waveform of a counter electromotive force generated when a mover of the motor is moved by an external force; a computing section for computing a counter electromotive force constant on the basis of the frequency value and the amplitude value; and a result display section for displaying a predetermined indication for a computed result or an expected computed result of the counter electromotive force constant. Then, an armature winding of the motor installed in the apparatus and the device for inspecting motor characteristics are electrically connected with a power supply line disconnected from the motor. After that, an external force is applied to the mover of the motor to cause the armature winding to generate a counter electromotive force. Then, a condition of the motor is determined on the basis of the computed result displayed on the result display section of the device for inspecting motor characteristics.

It is well known that a motor has a power generation function. Thus, when the mover of the motor is moved by an external force, a counter electromotive force or counter electromotive voltage is generated across terminals of the motor. In the present invention, a counter electromotive force constant Keφ, which is one of constants indicating characteristics of the motor, is computed to determine whether or not the characteristics of the motor are proper.

The counter electromotive force constant Keφ is computed using the following formula:

Keφ=Cx(Ke/f)

where Ke is a peak value of the counter electromotive voltage in units of V, f is a frequency value of the counter electromotive voltage, and C is a constant. Thus, the counter electromotive force constant Keφ can be calculated by measuring the peak and frequency values of the counter electromotive voltage. Accordingly, since the device for inspecting motor characteristics according to the present invention is intended to inspect a motor installed in an apparatus, an external force is applied, for example manually, to the mover of the motor when the motor is not driven and then is forcibly driven to generate a counter electromotive force. Because the external force is not constant, the counter electromotive force thus generated is represented by a waveform whose frequency is also not constant. There are various methods of acquiring a frequency from such a waveform. In the measuring section according to the present invention, for example, a zero crossing detecting circuit is utilized to measure the frequency by determining a period from a point at which the counter electromotive force waveform crosses a zero point to a point at which the counter electromotive force waveform crosses a next zero point as one cycle. Then, the counter electromotive force constant Keφ is calculated using an amplitude value of the waveform of which the frequency has been measured (a peak value of the counter electromotive voltage).

The result display section displays the computed result (a numerical value) for the counter electromotive force constant, which allows a measurer (a person who performs measurements) to determine whether or not the obtained counter electromotive force constant is proper for the motor. If the obtained counter electromotive force constant is not proper, it is found that the motor is in an abnormal state. The result display section may display a predetermined indication for an expected computed result of the counter electromotive force constant. This configuration facilitates determination as to whether or not the characteristics of the motor are proper even if it is not readily determined based on the counter electromotive force constant of the motor.

According to the present invention, any motor that generates a counter electromotive force may be inspected. Thus, any type of motor such as a DC motor, a linear motor, a servo motor, and a stepping motor may be inspected. If the motor to be inspected is a linear motor including a stator fixed to a stationary portion of an apparatus and a mover provided in a movable portion of the apparatus, the device for inspecting motor characteristics may further include an installation condition determining section for determining a size of a gap between a magnetic pole provided in the stator and a magnetic pole provided in the mover on the basis of the computed result to determine whether or not the motor is properly installed on the basis of the determined gap size. Because the gap size and the counter electromotive force constant are inversely proportional to each other, it is possible to know the gap size in the linear motor in the installed state utilizing such inversely proportional relationship, which allows determination as to the installation condition of the motor.

In general, the stator and the mover of a linear motor are separately formed, and assembled together at the location of use. That is, motor installation and gap adjustment is often performed by a user. Therefore, gap adjustment may not be adequately performed using a gap gauge, as a result of which a sufficient output of the linear motor may not be obtained. By using the device for inspecting motor characteristics according to the present invention, gap adjustment may be easily performed.

Preferably, the installation condition determining section for a linear motor determines that the gap size exceeds an appropriate range if the counter electromotive force constant falls below a predetermined threshold range and that the gap size falls below the appropriate range if the counter electromotive force constant exceeds the predetermined threshold range, and then the installation condition determining section determines that the motor is not properly installed in either case. This configuration further facilitates gap adjustment.

### BRIEF DESCRIPTION OF DRAWINGS

FIG. 1 shows an exemplary embodiment of a device for inspecting motor characteristics according to the present invention.

FIG. 2 is a block diagram showing the configuration of the embodiment of the present invention.

FIG. 3 is a flowchart showing an algorithm of software used to display a counter electromotive force constant and an indication for a computed result according to the embodiment of the present invention.

FIG. 4 shows a waveform of a counter electromotive force output when an external force is applied to a motor to drive the motor, according to the present invention.

### DESCRIPTION OF EMBODIMENTS

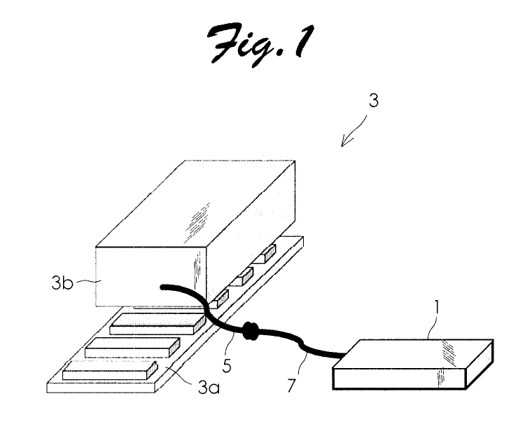

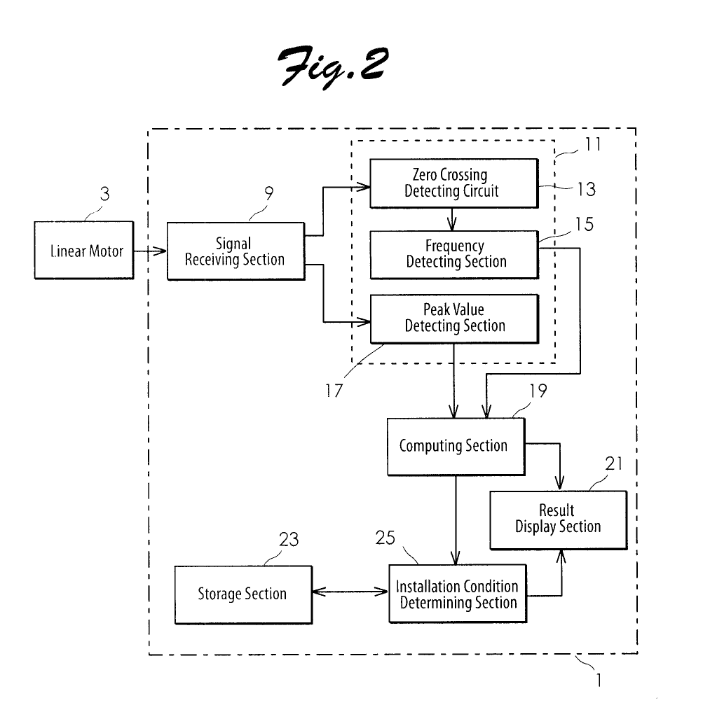

An embodiment of the present invention will now be described in detail below with reference to the accompanying drawings. FIG. 1 shows an exemplary embodiment of a device for inspecting motor characteristics according to the present invention. FIG. 2 is a block diagram showing the configuration of the embodiment of the present invention.

In the example embodiment shown in FIG. 1, a device for inspecting motor characteristics 1 is connected to a linear motor 3 to be inspected. The linear motor 3 includes a stator 3a fixed to a stationary portion of an apparatus and a mover 3b provided in a movable portion of the apparatus. The device for inspecting motor characteristics 1 is connected via a cable 7 to a power supply line 5 connected to a motor winding of the mover 3b of the linear motor 3 from which a power supply line has been disconnected.

The configuration and an overview of the embodiment of the present invention will be described with reference to FIG. 2. A signal receiving section 9 of the device for inspecting motor characteristics 1 receives a waveform of a counter electromotive force generated when the mover 3b of the linear motor 3 is moved by an external force. A measuring section 11 includes a zero crossing detecting circuit 13 and a frequency detecting circuit for detecting a frequency of a voltage of the counter electromotive force, and further includes a peak value detecting circuit 17 for detecting a peak value of the voltage of the counter electromotive force. A computing section 19 computes a counter electromotive force constant on the basis of the frequency value and the voltage peak value detected by the measuring section 11 and then causes an indication for a computed result of the counter electromotive force constant to be displayed on a result display section 21. In the present invention, further, a storage section 23 stores a table for determining an installation condition of the linear motor 3, and an installation condition determining section 25 causes an indication for the determined installation condition on the basis of the computed result to be displayed on the result display section 21.

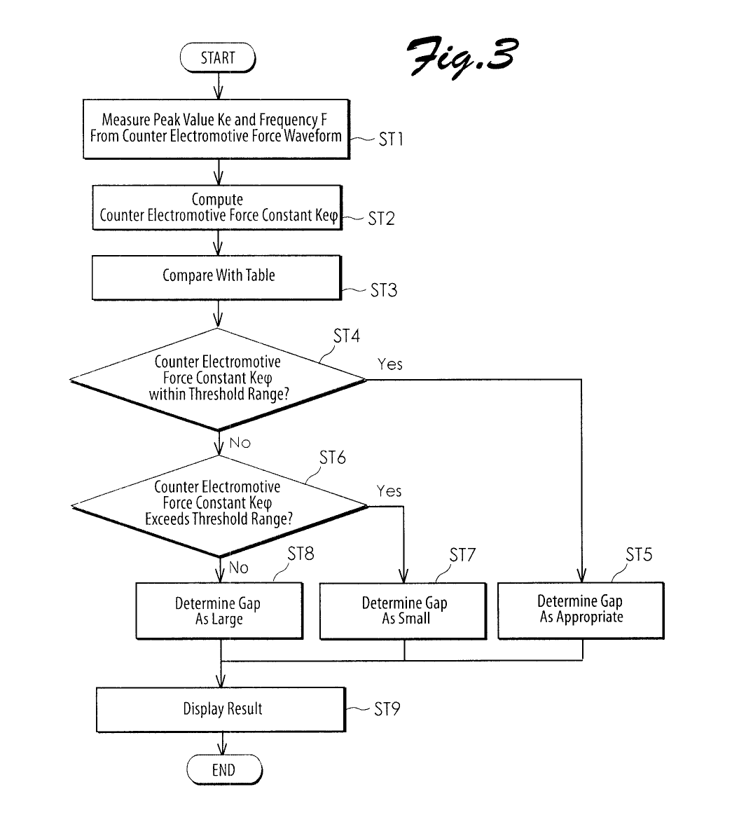

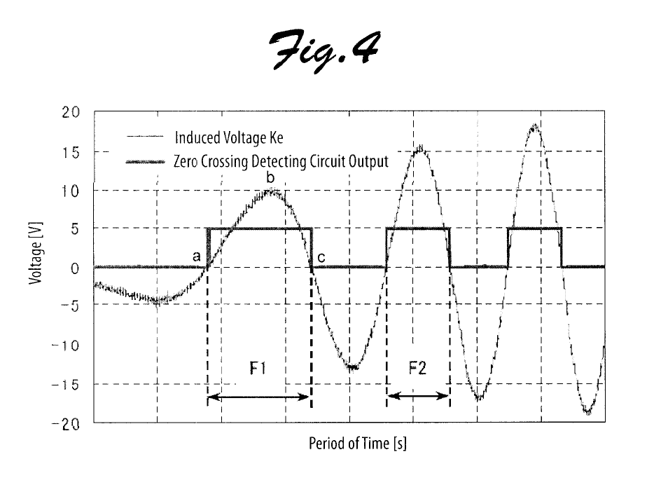

The flow from measurement to result display will be described in detail with reference to FIGS. 3 and 4. When the mover 3b of the linear motor 3 is moved by an external force, the signal receiving section 9 receives a waveform of a counter electromotive force generated by the linear motor 3 as shown in FIG. 4, and sends a signal to the measuring section 11. The measuring section 11 measures a frequency value and a voltage peak value (in step ST1).

Specifically, the frequency value is determined as follows. When the mover of the motor is moved by an external force, the motor generates a counter electromotive force whose frequency and voltage peak values are not constant as shown in FIG. 4. The zero crossing detecting circuit 13 outputs a voltage whose value changes from 0 V to 5 V and from 5 V to 0 V at points where the counter electromotive force waveform crosses the value of zero (zero crossing points). When the counter electromotive force waveform of FIG. 4 is input, the zero crossing detecting circuit 13 outputs a waveform of a zero crossing detection circuit output Vo of FIG. 4. On the counter electromotive force waveform of FIG. 4, for example, points a and c of the beginning waveform represent zero crossing points, and the frequency detecting circuit 15 detects a frequency f (=F1) for this portion from a cycle between the zero crossing points a and c.

Also, on the same beginning counter electromotive force waveform, the peak value detecting circuit 17 detects a point b as a peak value of the waveform.

Next, after receiving the detected frequency and peak values, the computing section 19 computes a counter electromotive force constant Keφ (in step ST2) using the following formula:

Keφ=Cx(Ke/f) (1)

where Ke is the peak value of the counter electromotive voltage in units of V, f is the frequency value of the counter electromotive voltage in units of Hz, and C is a constant.

The formula (1) is derived as follows.

If the motor is a linear motor, the counter electromotive force constant Keφ can be calculated using the following formula:

Keφ=Ke/v (2)

where Ke is the peak value of the counter electromotive voltage in units of V, and v is the velocity in units of m/s. Here, the following formula is satisfied:

v=2τ×f (3)

where τ is the pole pitch which is the distance between magnets in units of m, and f is the frequency value of the counter electromotive voltage in units of Hz. Thus, the formula (3) is substituted into the formula (2) as follows:

Keφ=Ke/(2τ×f)=(1/2τ)×(Ke/f)

Here, when 1/2τ is represented by C1, the following formula is obtained:

Keφ=C1×(Ke/f) (4 )

That is, in the case where the motor is a linear motor, the constant C in the formula (1) is obtained as C=C1=1/2τ.

In the case where the motor is a rotary motor, the counter electromotive force constant Keφ can be calculated using the following formula:

Keφ=Ke/N (5)

where Ke is the peak value of the counter electromotive voltage in units of V, and N is the rotational speed in units of rpm. Here, the following formula is satisfied:

N=(120×f)P (6)

where f is the frequency value of the counter electromotive voltage in units of Hz, and P is the number of poles. Thus, the formula (6) is substituted into the formula (5) as follows:

Keφ=Ke/(120×f)/P=(P/120)×(Ke/f)

Here, when P/120 is represented by C2, the following formula is obtained:

Keφ=C2×(Ke/f) (7)

That is, in the case where the motor is a rotary motor, the constant C in the formula (1) is obtained as C=C2=P/120.

After all, the counter electromotive force constant Keφ can be derived through multiplication of the constant C if the counter electromotive voltage peak value Ke in units of V and the counter electromotive voltage frequency value f in units of Hz are measured. The counter electromotive force constant Keφ can be completed using the formula (1) irrespective of the type of the motor, and can be calculated from the counter electromotive force waveform of FIG. 4 discussed earlier. While the constant C has been provided in advance in the computing section 19 in the embodiment, it is a matter of course that the constant C may be overwritten by an external device or an input section provided in the device of inspecting motor characteristics 1 for the purpose of generality.

Further in the present invention, the installation condition determining section 25 may determine the installation condition of the linear motor 3. The storage section 23 stores a table defining a size of a gap between a magnetic pole provided in the stator and a magnetic pole provided in the mover, and the computed counter electromotive force constant Keφ is compared with the table (in step ST3). It is determined whether or not the counter electromotive force constant Keφ falls within a certain threshold range (in step ST4). If the counter electromotive force constant Keφ falls within the threshold range, it is determined that the gap size falls within an appropriate range (in step ST5). If the counter electromotive force constant Keφ does not fall within the threshold range, it is determined whether or not the counter electromotive force constant Keφ exceeds the threshold range (in step ST6). If the counter electromotive force constant KO exceeds the threshold range, it is determined that the gap size falls below the appropriate range (in step ST7). If the counter electromotive force constant Keφ falls below the threshold range, it is determined that the gap size exceeds the appropriate range (in step ST8). Finally, the result display section 21 displays an indication for the computed result including the counter electromotive force constant (in step ST9).

While the installation condition determining section 25 is provided to determine whether or not the gap size is proper in the embodiment, it is not necessary to provide the installation condition determining section 25 if it is only necessary to obtain the counter electromotive force constant Keφ. If a motor other than a linear motor is to be inspected, it is not necessary to make a determination as to a gap size. In this case, a general determining section may be provided in place of the installation condition determining section 25 so that the result display section 21 displays an indication that the motor is in a normal condition if the counter electromotive force constant Keφ falls within the threshold range, and displays an indication that the motor is in an abnormal condition if the counter electromotive force constant Keφ does not fall within the threshold range.

According to the present invention, characteristics of a motor may be inspected on the basis of a counter electromotive force waveform. Thus, the characteristics of the motor may be inspected without removing the motor from an apparatus and without the need for a tachometer or a speed sensor.

While certain features of the invention have been described with reference to example embodiments, the description is not intended to be construed in a limiting sense. Various modifications of the example embodiments, as well as other embodiments of the invention, which are apparent to persons skilled in the art to which the invention pertains are deemed to lie within the spirit and scope of the invention.

What is claimed is:

1. A method of inspecting a condition of a motor installed in an apparatus without removing the motor from the apparatus, comprising:
preparing a device for inspecting motor characteristics that comprises:
a measuring section for measuring a frequency value and an amplitude value of a waveform of a counter electromotive force generated when a mover of the motor is moved by an external force;
a computing section for computing a counter electromotive force constant on the basis of the frequency value and the amplitude value; and
a result display section for displaying a predetermined indication for a computed result or an expected computed result of the counter electromotive force constant;
electrically connecting an armature winding of the motor installed in the apparatus and the device for inspecting motor characteristics with a power supply line disconnected from the motor;
applying an external force to the mover of the motor to cause the armature winding to generate a counter electromotive force; and
determining a condition of the motor on the basis of the computed result displayed on the result display section of the device for inspecting motor characteristics.

2. The method according to claim 1, wherein:
the motor is a linear motor comprising a stator fixed to a stationary portion of the apparatus and the mover provided in a movable portion of the apparatus; and
the device for inspecting motor characteristics further comprises an installation condition determining section for determining the size of a gap between a magnetic pole provided in the stator and a magnetic pole provided in the mover on the basis of the computed result to determine whether or not the motor is properly installed on the basis of the determined gap size.

3. The method according to claim 2, wherein:
the installation condition determining section determines that the gap size exceeds an appropriate range if the counter electromotive force constant falls below a predetermined threshold range and that the gap size falls below the appropriate range if the counter electromotive force constant exceeds the predetermined threshold range; and then the installation condition determining section determines that the motor is not properly installed in either case.

4. A device for inspecting motor characteristics, which inspects a condition of a motor installed in an apparatus without removing the motor from the apparatus, comprising:
a measuring section connected to the motor for measuring a frequency value and an amplitude value of a waveform of a counter electromotive force generated when a mover of the motor is moved by an external force;
a computing section for computing a counter electromotive force constant on the basis of the frequency value and the amplitude value; and
a result display section for displaying a predetermined indication for a computed result or an expected computed result of the counter electromotive force constant.

5. The device according to claim 4, further comprising:
an installation condition determining section for determining a size of a gap between a magnetic pole provided in a stator of the motor and a magnetic pole provided in the mover of the motor on the basis of the computed result to determine whether or not the motor is properly installed on the basis of the determined gap size,
wherein the motor is a linear motor comprising the stator fixed to a stationary portion of the apparatus and the mover provided in a movable portion of the apparatus.

6. The device (1) according to claim 5, wherein:
the installation condition determining section determines that the gap size exceeds an appropriate range if the counter electromotive force constant falls below a predetermined threshold range, and that the gap size falls below the appropriate range if the counter electromotive force constant exceeds the predetermined threshold range; and then the installation condition determining section determines that the motor is not properly installed in either case.
